(19) United States
(12) Patent Application Publication
(10) Pub. No.: US 2025/0038057 A1
(43) Pub. Date: Jan. 30, 2025

(54) SEMICONDUCTOR DEVICE

(71) Applicants: KABUSHIKI KAISHA TOSHIBA, Tokyo (JP); Toshiba Electronic Devices & Storage Corporation, Tokyo (JP)

(72) Inventor: Eitaro Miyake, Tachikawa Tokyo (JP)

(21) Appl. No.: 18/601,339

(22) Filed: Mar. 11, 2024

(30) Foreign Application Priority Data
Jul. 24, 2023 (JP) 2023-120015

(51) Int. Cl. H01L 23/24; H01L 23/00; H01L 23/31

(52) U.S. Cl. CPC H01L 23/24; H01L 23/3121; H01L 24/32; H01L 24/48; H01L 2224/32225; H01L 2224/48105; H01L 2224/48225; H01L 2924/351

(57) ABSTRACT

According to one embodiment, a semiconductor device includes a first substrate, a second substrate, a chip, and a spacer. The second substrate is provided to face the first substrate. The chip is provided on the first substrate and between the first substrate and the second substrate. The spacer is provided on the chip and couples the chip and the second substrate. The spacer has a first portion in contact with the chip and a second portion in contact with the second substrate. The second portion is larger in area than the first portion.

### CROSS-REFERENCE TO RELATED APPLICATION

This application is based upon and claims the benefit of priority from Japanese Patent Application No. 2023-120015, filed Jul. 24, 2023, the entire contents of which are incorporated herein by reference.

### FIELD

Embodiments described herein relate generally to a semiconductor device.

### BACKGROUND

A power module has been known as a semiconductor device. For such a power module, a configuration in which heat is radiated from both of the upper and lower surfaces of the module has been known.

### BRIEF DESCRIPTION OF THE DRAWINGS

FIG. 1 is a circuit diagram showing an example of a configuration of a semiconductor device according to an embodiment.

FIG. 2 is a perspective view showing an example of an appearance of the semiconductor device according to the embodiment.

FIG. 3 is a perspective view showing an example of an inner structure of the semiconductor device according to the embodiment.

FIG. 4 is a plan view showing an example of the inner structure of the semiconductor device according to the embodiment.

FIG. 5 is a plan view showing an example of the inner structure of the semiconductor device according to the embodiment.

FIG. 6 is a cross-sectional view showing an example of the inner structure of the semiconductor device according to the embodiment.

FIG. 7 is a cross-sectional view showing an example of the inner structure of the semiconductor device according to the embodiment.

FIG. 8 is a plan view showing an example of an inner structure of a semiconductor device according to a first modification.

FIG. 9 is a cross-sectional view showing an example of the inner structure of the semiconductor device according to the first modification.

FIG. 10 is a cross-sectional view showing an example of an inner structure of a semiconductor device according to a second modification.

FIG. 11 is a cross-sectional view showing an example of an inner structure of a semiconductor device according to a third modification.

FIG. 12 is a cross-sectional view showing an example of an inner structure of a semiconductor device according to a fourth modification.

FIG. 13 is a cross-sectional view showing an example of an inner structure of a semiconductor device according to a fifth modification.

FIG. 14 is a cross-sectional view showing an example of an inner structure of a semiconductor device according to a sixth modification.

FIG. 15 is a cross-sectional view showing an example of an inner structure of a semiconductor device according to a seventh modification.

FIG. 16 is a cross-sectional view showing an example of an inner structure of a semiconductor device according to an eighth modification.

### DETAILED DESCRIPTION

In general, according to one embodiment, a semiconductor device includes a first substrate, a second substrate, a chip, and a spacer. The second substrate is provided to face the first substrate. The chip is provided on the first substrate and between the first substrate and the second substrate. The spacer is provided on the chip and couples the chip and the second substrate. The spacer has a first portion in contact with the chip and a second portion in contact with the second substrate. The second portion is larger in area than the first portion.

Hereinafter, embodiments will be described with reference to the accompanying drawings. In the following description, constituent elements having substantially the same function and configuration will be assigned the same reference symbol. Furthermore, an embodiment described below will give an example of the technical idea. The embodiment does not specify the material, shape, structure, arrangement, etc. of structural components. Various modifications can be made to the embodiment.

### Embodiment

A semiconductor device according to an embodiment will be described. A semiconductor device 1 according to the embodiment is a power module. The semiconductor device 1 is used in, for example, a power conversion device of an electric vehicle.

### <1>Configuration

### <1-1>Configuration of Circuit of Semiconductor Device

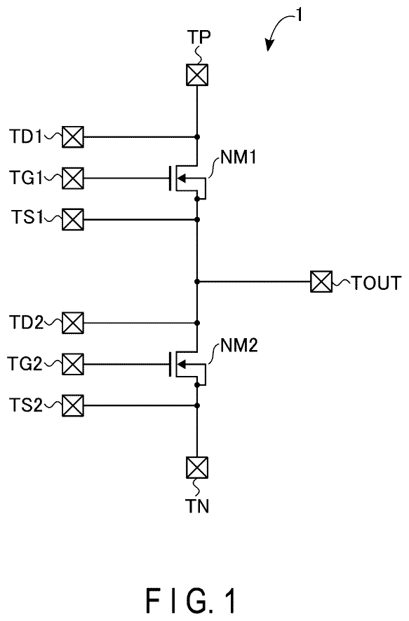

FIG. 1 is a circuit diagram showing an example of a configuration of a semiconductor device according to an embodiment. The semiconductor device 1 according to the embodiment includes, for example, a half-bridge circuit. As shown in FIG. 1, the semiconductor device 1 includes terminals TP, TN, TOUT, TG1, TG2, TD1, TD2, TS1, and TS2, and transistors NM1 and NM2.

Each of the terminals TP and TN is a power supply terminal of the semiconductor device 1. A positive power supply voltage is applied to the terminal TP. A negative power supply voltage is applied to the terminal TN.

The terminal TOUT is an output terminal of the semiconductor device 1.

Each of the terminals TG1 and TG2 is a control terminal of the semiconductor device 1.

Each of the terminals TD1, TD2, TS1, and TS2 is a terminal for monitoring operations of the semiconductor device 1.

Each of the transistors NM1 and NM2 is, for example, an N-type MOS transistor. A drain of the transistor NM1 is coupled to the terminal TP. A source of the transistor NM1 is coupled to the terminal TOUT. A gate of the transistor NM1 is coupled to the terminal TG1. A drain of the transistor NM2 is coupled to the terminal TOUT. A source of the transistor NM2 is coupled to the terminal TN. A gate of the transistor NM2 is coupled to the terminal TG2.

The drain of the transistor NM1 is coupled to the terminal TD1. The source of the transistor NM1 is coupled to the terminal TS1. The drain of the transistor NM2 is coupled to the terminal TD2. The source of the transistor NM2 is coupled to the terminal TS2.

### <1-2>Configuration of Package of Semiconductor Device

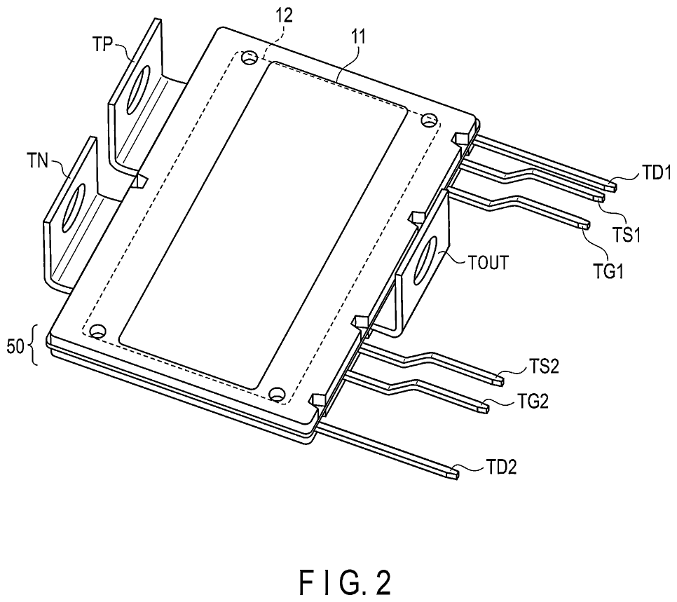

FIG. 2 is a perspective view showing an example of an appearance of the semiconductor device according to the embodiment. The semiconductor device 1 has, for example, a thin rectangular parallelepiped shape. Hereinafter, a thickness direction of the semiconductor device 1 will be referred to as a “vertical direction”. Furthermore, in a case where a constituent element of the semiconductor device 1 has two faces facing each other in the vertical direction, these faces will be respectively referred to as an “upper surface” and a “lower surface”.

The semiconductor device 1 further includes substrates 11 and 12 and a sealing member 50. Each of the terminals TP, TN, TOUT, TG1, TG2, TD1, TD2, TS1, and TS2 has a portion serving as a terminal in charge of electrical coupling to the exterior and exposed to the exterior of the sealing member 50. Each of the substrates 11 and 12 has a portion exposed to the exterior of the sealing member 50. Hereinafter, the surface on which the substrate 11 is exposed will be referred to as an “upper surface”, and the surface on which the substrate 12 is exposed will be referred to as a “lower surface”.

The substrates 11 and 12 are each an insulating circuit substrate in which conductors are respectively bonded to both surfaces of a plate-shaped insulator. The insulator is, for example, aluminum oxide. The conductor is, for example, copper. The substrates 11 and 12 are provided to face each other. Each of the substrates 11 and 12 has a circuit pattern formed on a surface facing the inside of the semiconductor device 1. The substrate 11 is provided in such a manner that a portion of the substrate 11 is exposed on the upper surface of the sealing member 50. The substrate 12 is provided in such a manner that a portion of the substrate 12 is exposed on the lower surface of the sealing member 50. Each of the portion of the substrate 11 exposed on the upper surface of the sealing member 50 and the portion of the substrate 12 exposed on the lower surface of the sealing member 50 also functions as a heat radiation board which radiates heat generated inside the semiconductor device 1 to the outside thereof.

Each of the terminals TP, TN, and TOUT is provided in such a manner as to be exposed on one side surface of the sealing member 50. For example, the terminals TP and TN protrude from a first surface which is one side surface of the sealing member 50. For example, of the side surfaces of the sealing member 50, the terminal TOUT protrudes from a substantial center of a second surface facing the first surface from which the terminals TP and TN protrude. Each of the terminals TP, TN, and TOUT is bent at its protruding extension to form a letter L shape and has a circular opening at its extension formed into the letter L shape.

The terminals TG1, TD1, and TS1 are provided in such a manner as to be exposed on one side surface of the sealing member 50. For example, of the side surfaces of the sealing member 50, the terminals TG1, TD1, and TS1 are adjacent to the terminal TOUT on the second surface, and are provided between the terminal TOUT and the end of the second surface. The terminals TG1, TD1, and TS1 protrude from one side surface of the sealing member 50.

The terminals TG2, TD2, and TS2 are provided in such a manner as to be exposed on one side surface of the sealing member 50. For example, of the side surfaces of the sealing member 50, the terminals TG2, TD2, and TS2 are adjacent to the terminal TOUT on the second surface, and are provided between the terminal TOUT and the end of the second surface and on the side opposite to a portion in which the terminals TG1, TD1, and TS1 are provided. The terminals TG2, TD2, and TS2 protrude from the side surface of the sealing member 50.

The sealing member 50 is an insulating member configured to physically and electrically protect the inner structure of the semiconductor device 1 from the outside. The sealing member 50 forms the outer shape of the semiconductor device 1.

### <1-3>Inner Structure of Semiconductor Device

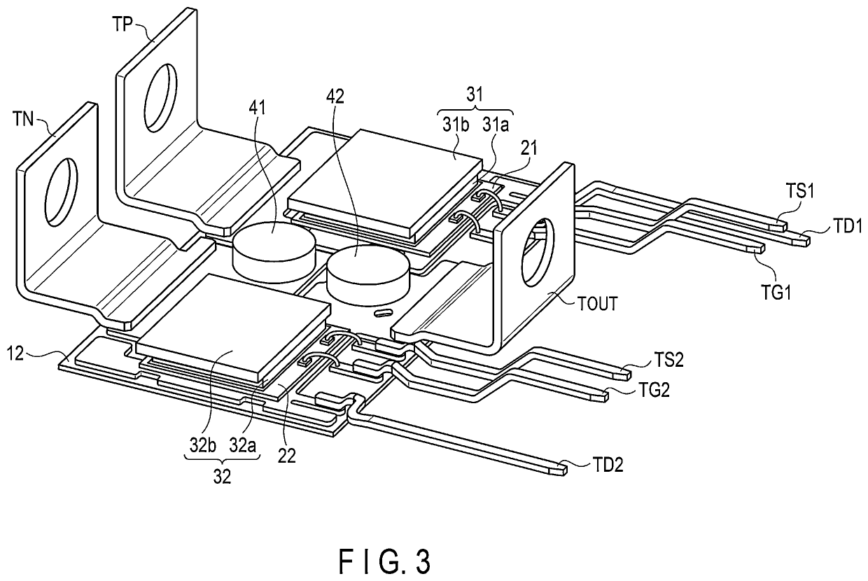

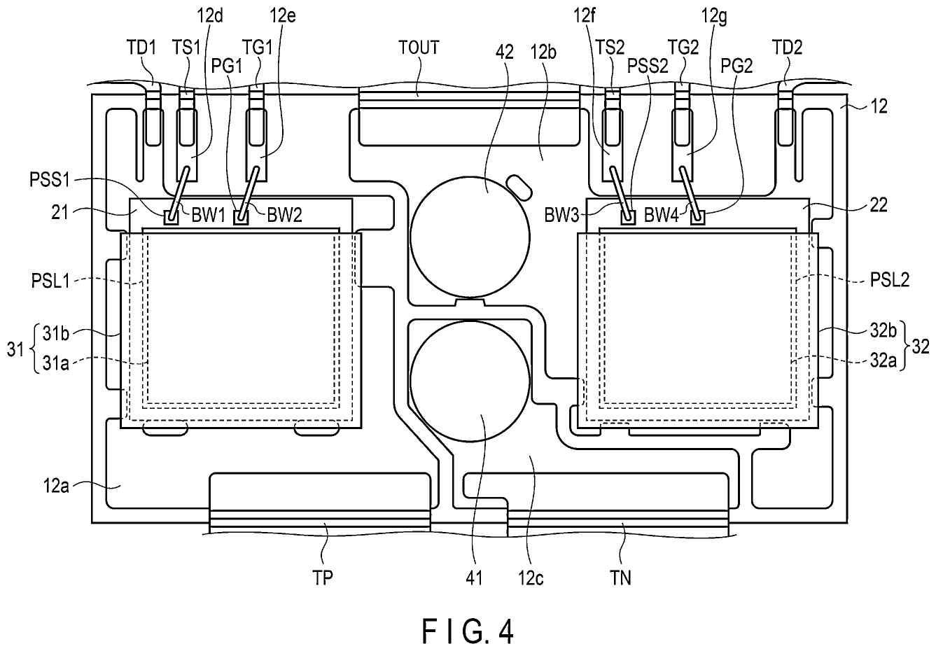

With reference to FIG. 3 and FIG. 4, the inner structure of the semiconductor device 1 will be described. FIG. 3 is a perspective view showing an example of the inner structure of the semiconductor device according to the embodiment. FIG. 4 is a plan view showing an example of the inner structure of the semiconductor device according to the embodiment. The substrate 11 and the sealing member 50 are omitted from FIG. 3 and FIG. 4. The semiconductor device 1 further includes, as its inner structure, chips 21 and 22, spacers 31 and 32, and inter-substrate spacers 41 and 42. Furthermore, the substrate 12 includes circuit patterns 12a, 12b, 12c, 12d, 12e, 12f, and 12g.

Each of the circuit patterns 12a, 12b, 12c, 12d, 12e, 12f, and 12g is a conductor provided on the substrate 12 and is, for example, copper. The circuit pattern 12a is coupled to the terminals TP and TD1. The circuit pattern 12b is coupled to the terminals TOUT and TD2. The circuit pattern 12c is coupled to the terminal TN. The circuit pattern 12d is coupled to the terminal TS1. The circuit pattern 12e is coupled to the terminal TG1. The circuit pattern 12f is coupled to the terminal TS2. The circuit pattern 12g is coupled to the terminal TG2.

Each of the chips 21 and 22 is a chip of a power semiconductor. Specifically, for example, each of the chips 21 and 22 includes an N-type MOS transistor. The transistor included in the chip 21 corresponds to the transistor NM1 described with reference to FIG. 1. The transistor included in the chip 22 corresponds to the transistor NM2 described with reference to FIG. 1. Each of the chips 21 and 22 has, for example, a quadrilateral flat plate shape. The lower surface of each of the chips 21 and 22 is used as an electrode corresponding to the drain.

Pads PSL1 and PSS1 each corresponding to the source, and a pad PG1 corresponding to the gate are provided on the upper surface of the chip 21. The pad PSL1 is a large pad that occupies a major part of the upper surface of the chip 21. The pad PSL1 is provided at the central portion of the upper surface of the chip 21. The pads PSS1 and PG1 are small pads. The pads PSS1 and PG1 are provided to be adjacent to each other along one side on the upper surface of the chip 21.

The upper surface of the chip 22 is similar to the upper surface of the chip 21. That is, pads PSL2 and PSS2 each corresponding to the source, and a pad PG2 corresponding to the gate are provided on the upper surface of the chip 22. The pad PSL2 is a large pad that occupies a major part of the upper surface of the chip 22. The pad PSL2 is provided at the central portion of the upper surface of the chip 22. The pads PSS2 and PG2 are small pads. The pads PSS2 and PG2 are provided to be adjacent to each other along one side on the upper surface of the chip 22.

The chip 21 is provided on the circuit pattern 12a. Specifically, the chip 21 is provided in such a manner that the side along which the pads PSS1 and PG1 are provided to be adjacent to each other is oriented in the direction in which the terminals TG1, TD1, and TS1 are provided. A drain electrode provided on the lower surface of the chip 21 is electrically coupled to the circuit pattern 12a. This electrically couples the drain electrode provided on the lower surface of the chip 21 to the terminals TP and TD1. The pad PSS1 provided on the upper surface of the chip 21 is electrically coupled to the circuit pattern 12d by a bonding wire BW1. This electrically couples the pad PSS1 to the terminal TS1. The pad PG1 provided on the upper surface of the chip 21 is electrically coupled to the circuit pattern 12e by a bonding wire BW2. This electrically couples the pad PG1 to the terminal TG1.

The chip 22 is provided on the circuit pattern 12b. Specifically, the chip 22 is provided in such a manner that the side along which the pads PSS2 and PG2 are provided to be adjacent to each other is oriented in the direction in which the terminals TG2, TD2, and TS2 are provided. The drain electrode provided on the lower surface of the chip 22 is electrically coupled to the circuit pattern 12b. This electrically couples the drain electrode provided on the lower surface of the chip 22 to the terminals TOUT and TD2. The pad PSS2 provided on the upper surface of the chip 22 is electrically coupled to the circuit pattern 12f by a bonding wire BW3. This electrically couples the pad PSS2 to the terminal TS2. The pad PG2 provided on the upper surface of the chip 22 is electrically coupled to the circuit pattern 12g by a bonding wire BW4. This electrically couples the pad PG2 to the terminal TG2.

The spacer 31 is provided on the pad PSL1 provided on the upper surface of the chip 21. The spacer 32 is provided on the pad PSL2 provided on the upper surface of the chip 22. Each of the spacers 31 and 32 is a conductor. Each of the spacers 31 and 32 is, for example, a composite material of aluminum and silicon carbide. Each of the spacers 31 and 32 has a structure in which the upper surface is greater in area than the lower surface. The lower surface of the spacer 31 is smaller in area than the upper surface of the chip 21. The lower surface of the spacer 32 is smaller in area than the upper surface of the chip 22.

For example, the spacer 31 includes spacers 31a and 31b. Each of the spacers 31a and 31b is a rectangular flat plate in which the upper surface and the lower surface are substantially equal in area to each other. The spacer 31a has upper and lower surfaces that can be fit within the upper surface of the chip 21 when viewed from the top. The long sides of each of the upper and lower surfaces of the spacer 31b are longer than the long sides of each of the upper and lower surfaces of the spacer 31a. The short sides of each of the upper and lower surfaces of the spacer 31b are longer than the short sides of each of the upper and lower surfaces of the spacer 31a. The spacer 31 has a structure in which the spacer 31b is overlapped on the spacer 31a in such a manner that one side of the spacer 31a and one side of the spacer 31b are aligned with each other. The spacer 31 is provided in such a manner that one side of the spacer 31a and one side of the spacer 31b overlap so that they are aligned with each other and are oriented toward the side along which the pads PSS1 and PG1 of the chip 21 are provided to be adjacent to each other. The spacer 31 is electrically coupled to the pad PSL1.

The same applies to the spacer 32. That is, the spacer 32 includes spacers 32a and 32b. Each of the spacers 32a and 32b is a rectangular flat plate in which the upper surface and the lower surface are substantially equal in area to each other. The spacer 32a has upper and lower surfaces that can be fit within the upper surface of the chip 22 when viewed from the top. The long sides of each of the upper and lower surfaces of the spacer 32b are longer than the long sides of each of the upper and lower surfaces of the spacer 32a. The short sides of each of the upper and lower surfaces of the spacer 32b are longer than the short sides of the upper and lower surfaces of the spacer 32a. The spacer 32 has a structure in which the spacer 32b is overlapped on the spacer 32a in such a manner that one side of the spacer 32a and one side of the spacer 32b are aligned with each other. The spacer 32 is provided in such a manner that one side of the spacer 32a and one side of the spacer 32b overlap so that they are aligned with each other and are oriented toward the side along which the pads PSS2 and PG2 of the chip 22 are provided to be adjacent to each other. The spacer 32 is electrically coupled to the pad PSL2.

The inter-substrate spacer 41 is provided on the circuit pattern 12c and between the chips 21 and 22. The inter-substrate spacer 42 is provided on the circuit pattern 12b and between the chips 21 and 22. Each of the inter-substrate spacers 41 and 42 is a conductor. Each of the inter-substrate spacers 41 and 42 is, for example, a composite material of aluminum and silicon carbide. The inter-substrate spacers 41 and 42 each have, for example, a cylindrical shape. The lower surface of the inter-substrate spacer 41 is electrically coupled to the circuit pattern 12c. This electrically couples the inter-substrate spacer 41 to the terminal TN. The lower surface of the inter-substrate spacer 42 is electrically coupled to the circuit pattern 12b. This electrically couples the inter-substrate spacer 42 to the terminals TOUT and TD2 and to the drain electrode provided on the lower surface of the chip 22. The upper surface of each of the inter-substrate spacers 41 and 42 is substantially equal in height to the upper surface of each of the spacers 31 and 32.

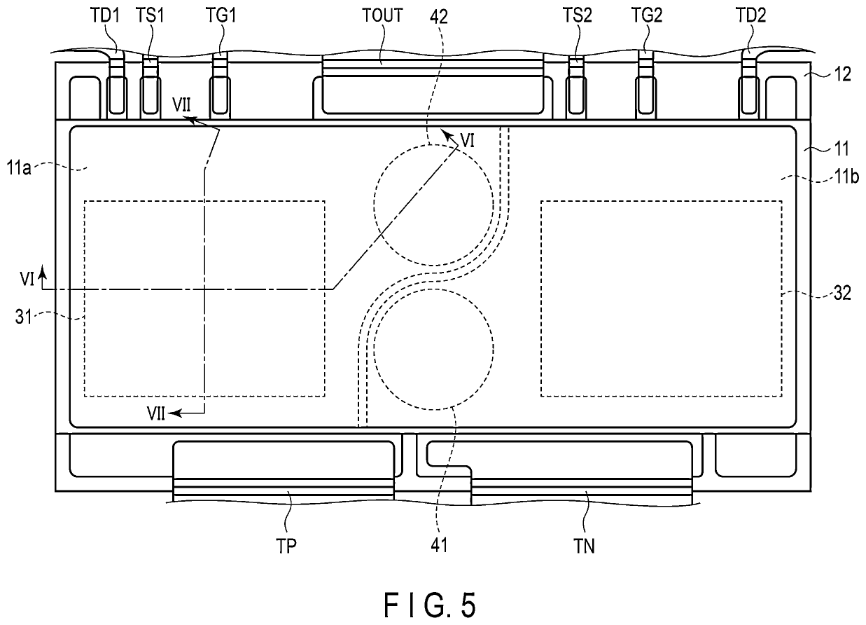

FIG. 5 is a plan view showing an example of the inner structure of the semiconductor device according to the embodiment. The sealing member 50 is omitted from FIG. 5. As shown in FIG. 5, the circuit pattern 11a provided on the lower surface of the substrate 11 electrically couples the upper surface of the spacer 31 to the upper surface of the inter-substrate spacer 42. This electrically couples the pad PSL1 of the chip 21 to the terminals TOUT and TD2 and to the drain electrode provided on the lower surface of the chip 22. The circuit pattern 11b provided on the lower surface of the substrate 11 electrically couples the upper surface of the spacer 32 to the upper surface of the inter-substrate spacer 41. This electrically couples the pad PSL2 of the chip 22 to the terminal TN.

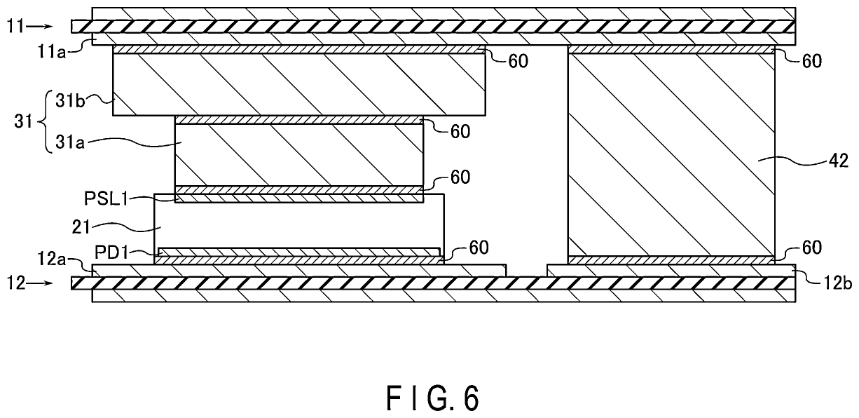

FIG. 6 is a cross-sectional view showing an example of the inner structure of the semiconductor device according to the embodiment. FIG. 6 shows a sectional view taken along the line VI-VI shown in FIG. 5. The sealing member 50 is omitted from FIG. 6. The circuit pattern 12a on the substrate 12 and the drain electrode PD1 provided on the lower surface of the chip 21 are joined together by a joint layer 60. The pad PSL1 provided on the upper surface of the chip 21 and the lower surface of the spacer 31 are joined together by the joint layer 60. The upper surface of the spacer 31a and the lower surface of the spacer 31b are joined together by the joint layer 60. The upper surface of the spacer 31 and the circuit pattern 11a provided on the substrate 11 are joined together by the joint layer 60. The lower surface of the inter-substrate spacer 42 and the circuit pattern 12b on the substrate 12 are joined together by the joint layer 60. The upper surface of the inter-substrate spacer 42 and the circuit pattern 11a provided on the substrate 11 are joined together by the joint layer 60. The joint layer 60 is, for example, solder.

The same applies to the chip 22, the spacer 32, and the inter-substrate spacer 41. That is, the circuit pattern 12b on the substrate 12 and the drain electrode provided on the lower surface of the chip 22 are joined together by the joint layer. The pad PSL2 provided on the upper surface of the chip 22 and the lower surface of the spacer 32 are joined together by the joint layer. The upper surface of the spacer 32a and the lower surface of the spacer 32b are joined together by the joint layer. The upper surface of the spacer 32 and the circuit pattern 11b provided on the substrate 11 are joined together by the joint layer. The lower surface of the inter-substrate spacer 41 and the circuit pattern 12c on the substrate 12 are joined together by the joint layer. The upper surface of the inter-substrate spacer 41 and the circuit pattern 11b provided on the substrate 11 are joined together by the joint layer. The joint layer is, for example, solder.

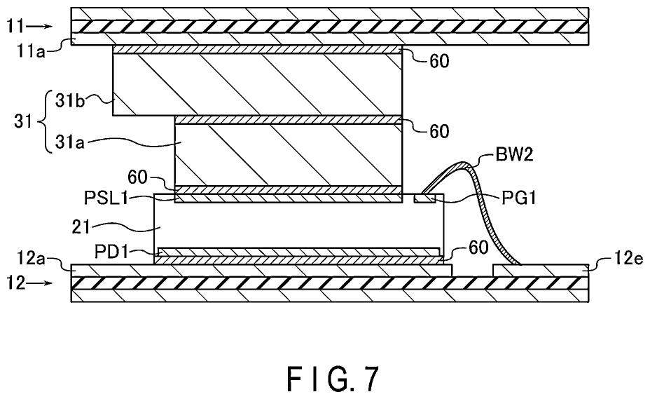

FIG. 7 is a cross-sectional view showing an example of the inner structure of the semiconductor device according to the embodiment. FIG. 7 shows a sectional view taken along the line VII-VII shown in FIG. 5. The sealing member 50 is omitted from FIG. 7. The pad PG1 provided on the upper surface of the chip 21 and the circuit pattern 12e are electrically coupled to each other by the bonding wire BW2. In the semiconductor device 1 according to the embodiment, the spacer 31 is not provided above the pad PG1.

Similarly, the spacer 31 is not provided above the pad PSS1. As described above, in the semiconductor device 1 according to the embodiment, the pad and the spacer on which wire bonding is performed are provided in such a manner that they do not overlap when viewed from the top.

Meanwhile, a thermal expansion coefficient of each element used in the semiconductor device 1 according to the embodiment is as follows. The chips 21 and 22 mainly formed of silicon have a thermal expansion coefficient of, for example, 2×10⁻⁶/K to 5×10⁻⁶/K. Copper forming the circuit pattern of the substrates 11 and 12 has a thermal expansion coefficient of, for example, 17×10⁻⁶/K. A composite material of aluminum and silicon carbide included in the spacers 31 and 32 and the inter-substrate spacers 41 and 42 has a thermal expansion coefficient of, for example, 10×10⁻⁶/K. As described above, the thermal expansion coefficient of the composite material of aluminum and silicon carbide included in the spacers 31 and 32 is greater than that of each of the chips 21 and 22 and is smaller than that of copper included in the substrates 11 and 12.

The semiconductor device 1 according to the embodiment realizes an improved heat radiation performance.

The spacer provided on the chip is a portion of a current path that couples the source of the transistor included in the chip to an external connection terminal and is also one of the heat radiation paths that transmit heat generated in the chip to the substrate 11.

According to the embodiment, the spacer provided on the chip is provided in such a manner that the upper surface to be joined to the substrate is larger in area than the lower surface to be joined to the chip. By this, in transmission of heat from the chip to the substrate via the spacer, heat is spread throughout a larger area, so that the heat radiation performance can be improved.

Furthermore, in the semiconductor device 1 according to the embodiment, the thermal expansion coefficient of the spacer provided on the chip is greater than that of each of the chips and is smaller than the that of copper included in the substrate. By this, the semiconductor device 1 according to the embodiment can prevent peeling of the joint between the chip and the spacer and the joint between the spacer and substrate even in a case where a temperature repeatedly rises and falls.

### <2>Modifications, etc.

As an example of the spacers 31 and 32, the above embodiment described the structure in which one flat plate with a small area and another flat plate with a large area are provided in such a manner that one side of the flat plate and one side of another flat plate overlap to be aligned with each other. The spacers 31 and 32 are not limited to this. Hereinafter, a plurality of modifications will be described.

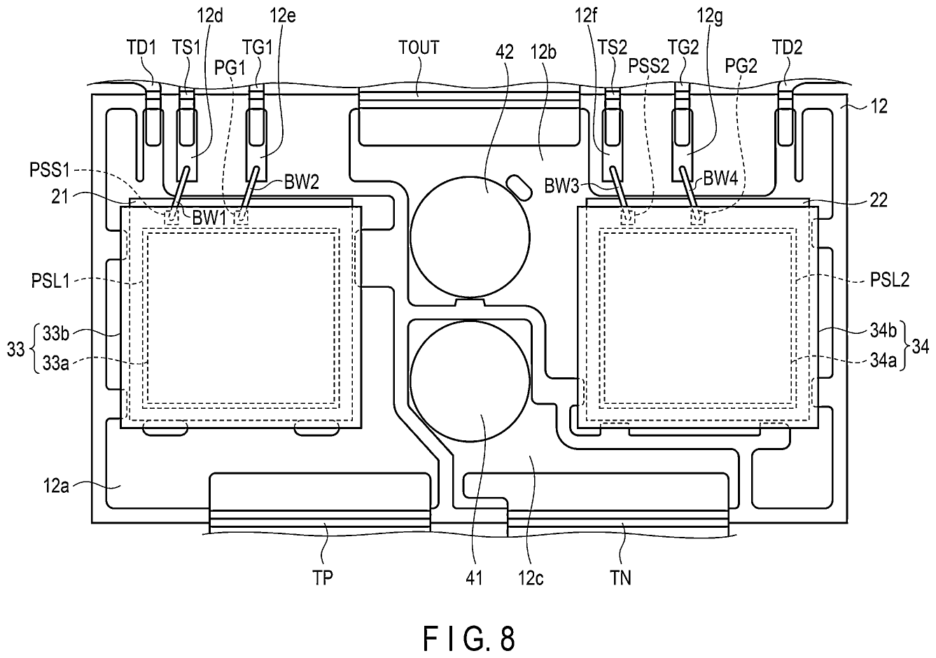

FIG. 8 is a plan view showing an example of an inner structure of a semiconductor device according to a first modification. FIG. 8 corresponds to FIG. 4 illustrating the above embodiment. The substrate 11 and the sealing member 50 are omitted from FIG. 8. The first modification differs from the embodiment described above in that the spacer 31 is replaced with a spacer 33, and the spacer 32 is replaced with a spacer 34. The spacer 33 includes spacers 33a and 33b. Each of the spacers 33a and 33b is a quadrilateral flat plate in which the upper surface and the lower surface are substantially equal in area to each other. The spacer 33a has upper and lower surfaces that can be fit within the upper surface of the chip 21 when viewed from the top. The spacer 33b has upper and lower surfaces within which the upper surface of the spacer 33a can be fit when viewed from the top. The spacer 33 has a structure in which the spacer 33b is overlapped on the spacer 33a. More specifically, the spacers 33a and 33b are provided to overlap with each other in such a manner that the upper surface of the spacer 33a is fit within the lower surface of the spacer 33b and the lower surface of the spacer 33b projects from four sides of the upper surface of the spacer 33a.

The spacer 34 has a similar configuration to that of the spacer 33. That is, the spacer 34 includes spacers 34a and 34b. Each of the spacers 34a and 34b is a quadrilateral flat plate in which the upper surface and the lower surface are substantially equal in area to each other. The spacer 34a has upper and lower surfaces that can be fit within the upper surface of the chip 22 when viewed from the top. The spacer 34b has upper and lower surfaces within which the upper surface of the spacer 34a can be fit when viewed from the top. The spacer 34 has a configuration in which the spacer 34b is overlapped on the spacer 34a. More specifically, the spacers 34a and 34b are provided to overlap with each other in such a manner that the upper surface of the spacer 34a is fit within the lower surface of the spacer 34b and the lower surface of the spacer 34b projects from four sides of the upper surface of the spacer 34a.

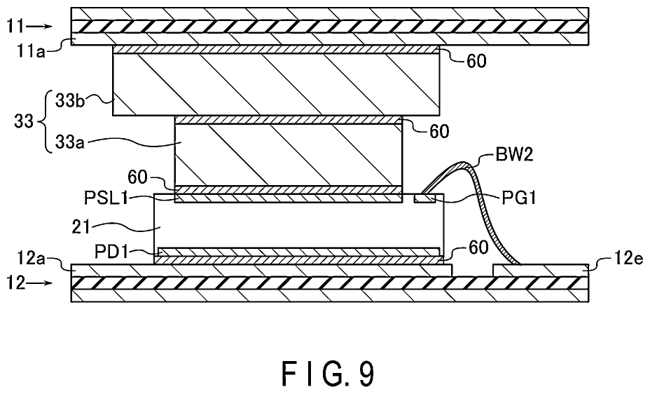

FIG. 9 is a cross-sectional view showing an example of the inner structure of the semiconductor device according to the first modification. FIG. 9 corresponds to FIG. 7 illustrating the above embodiment. The sealing member 50 is omitted from FIG. 9. As shown in FIG. 9, in the semiconductor device according to the first modification, the spacer 33b protrudes toward the upper side of the pad PG1.

The spacer 33 thus configured has a shape in which the spacer 33b protrudes from all of the four sides above the spacer 33a, and the spacer 34 thus configured has a shape in which the spacer 34b protrudes from all of the four sides above the spacer 34a. The spacers may be configured in this manner. In a case where the spacers are configured in a manner described in the first modification, it is assumed that the spacers 33 and 34 are respectively provided on the chips 21 and 22 after completion of the step of wire bonding. Furthermore, it is assumed that each bonding wire and each spacer are provided in such a manner that each bonding wire and each spacer are not in contact with each other.

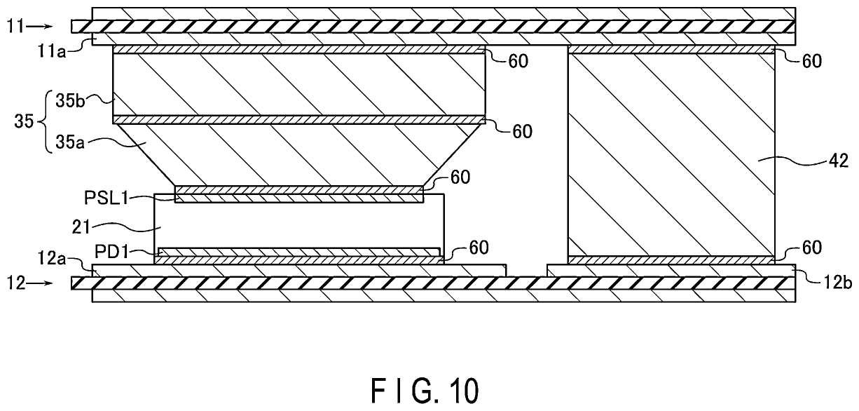

FIG. 10 is a cross-sectional view showing an example of an inner structure of a semiconductor device according to a second modification. FIG. 10 corresponds to FIG. 6 illustrating the above embodiment. The sealing member 50 is omitted from FIG. 10. The second modification differs from the embodiment described above in that the spacer 31 is replaced with a spacer 35. The spacer 35 includes the spacers 35a and 35b. The spacer 35a is shaped into a quadrilateral pyramid in which the upper surface and the lower surface are each a quadrangle and are parallel to each other, and the upper surface is greater in area than the lower surface. The lower surface of the spacer 35a can be fit within the upper surface of the chip 21. The spacer 35b is a quadrilateral flat plate in which the upper surface and the lower surface are substantially equal in area to each other. The spacer 35b has the lower surface within which the upper surface of the spacer 35a can be fit. The spacer 35 has a configuration in which the spacer 35b is overlapped on the spacer 35a. More specifically, the spacers 35a and 35b are provided to overlap with each other in such a manner that the upper surface of the spacer 35a is fit within the lower surface of the spacer 35b. The spacer 35a and the spacer 35b are joined together by the joint layer 60. The joint layer 60 is, for example, solder.

The spacer 35 thus configured has a portion in which a side wall of the spacer is inclined in such a manner the spacer expands as it extends from the lower portion to the upper portion. As described above, the spacers may be configured in such a manner as to have inclined side walls.

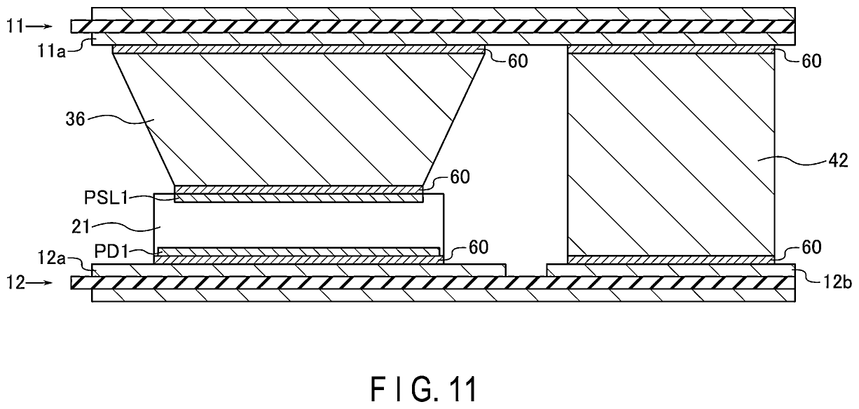

FIG. 11 is a cross-sectional view showing an example of an inner structure of a semiconductor device according to a third modification. FIG. 11 corresponds to FIG. 6 illustrating the above embodiment. The sealing member 50 is omitted from FIG. 11. The third modification differs from the embodiment described above in that the spacer 31 is replaced with a spacer 36. The spacer 36 is shaped into a quadrangular pyramid in which the upper surface and the lower surface are each a quadrilateral and are parallel to each other, and the upper surface is greater in area than the lower surface. The lower surface of the spacer 36 can be fit within the upper surface of the chip 21.

As described above, the spacers may be composed only of components having side walls inclined. Furthermore, the spacers may be composed of a single component.

The spacer 36 can also be expressed as having a configuration in which its cross-sectional area on a plane in parallel to the substrates 11 and 12 continuously increases from the lower surface to the upper surface.

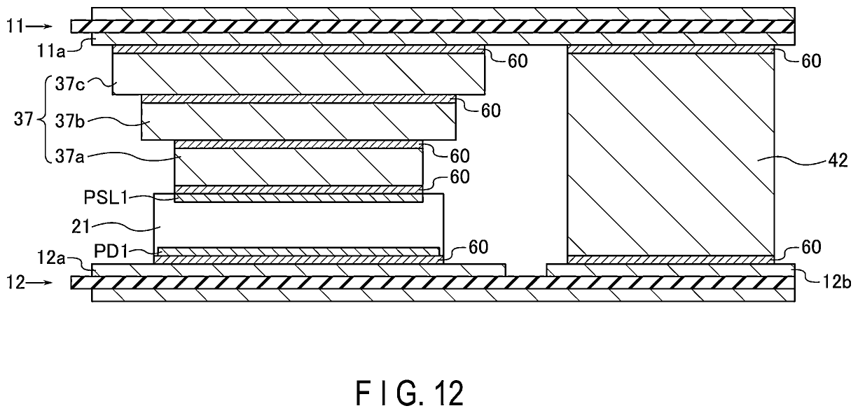

FIG. 12 is a cross-sectional view showing an example of an inner structure of a semiconductor device according to a fourth modification. FIG. 12 corresponds to FIG. 6 illustrating the above embodiment. The sealing member 50 is omitted from FIG. 12. The fourth modification differs from the embodiment described above in that the spacer 31 is replaced with a spacer 37. The spacer 37 includes spacers 37a, 37b, and 37c. Each of the spacers 37a, 37b, and 37c is a quadrilateral flat plate in which the upper surface and the lower surface are substantially equal in area to each other. The spacer 37a has upper and lower surfaces that can be fit within the upper surface of the chip 21 when viewed from the top. The spacer 37b has upper and lower surfaces within which the upper surface of the spacer 37a can be fit when viewed from the top. The spacer 37c has upper and lower surfaces within which the upper surface of the spacer 37b can be fit when viewed from the top. The spacer 37 has a configuration in which the spacer 37b is overlapped on the spacer 37a, and the spacer 37c is overlapped on the spacer 37b. More specifically, the spacers 37a, 37b, and 37c are provided to overlap with each other in such a manner that the upper surface of the spacer 37a is fit within the lower surface of the spacer 37b and the upper surface of the spacer 37b is fit within the lower surface of the spacer 37c. The spacers 37a and 37b are joined together by the joint layer 60, and the spacers 37b and 37c are joined together by the joint layer 60. The joint layer 60 is, for example, solder.

As described above, the number of components composing the spacer may be one or more, and is not limited to one or two. The spacer may be composed of the given number of components.

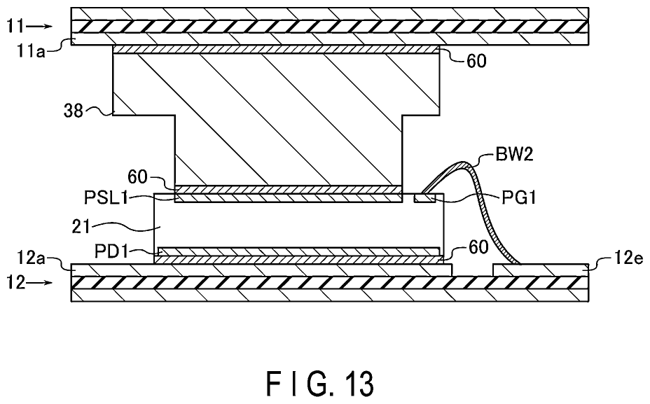

FIG. 13 is a cross-sectional view showing an example of an inner structure of a semiconductor device according to a fifth modification. FIG. 13 corresponds to FIG. 7 illustrating the above embodiment. The sealing member 50 is omitted from FIG. 13. The fifth modification differs from the first modification in that the spacer 33 composed of the plurality of components is replaced with a spacer 38 composed of a single component. The spacer 38 has a shape similar to a shape obtained by overlapping the spacers 33a and 33b in the first modification.

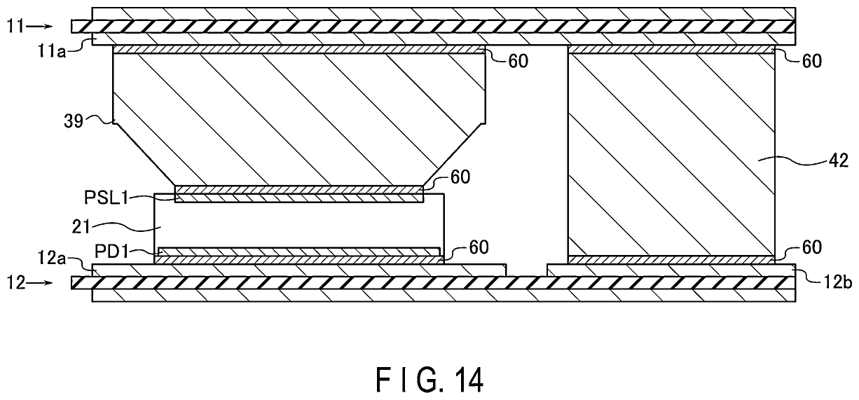

FIG. 14 is a cross-sectional view showing an example of an inner structure of a semiconductor device according to a sixth modification. FIG. 14 corresponds to FIG. 6 illustrating the above embodiment. The sealing member 50 is omitted from FIG. 14. The sixth modification differs from the second modification in that the spacer 35 composed of the plurality of components is replaced with a spacer 39 composed of a single component. The spacer 39 has a shape similar to a shape obtained by overlapping the spacers 35a and 35b in the second modification.

As described above, the spacer composed of the plurality of components described in the above embodiment and modifications may be composed of a single component formed into a similar shape to that of the spacer.

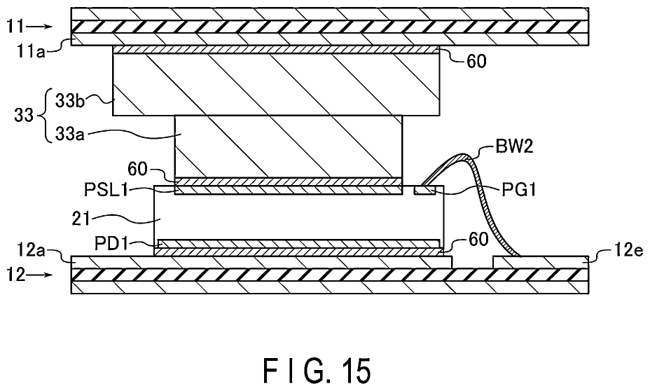

FIG. 15 is a cross-sectional view showing an example of an inner structure of a semiconductor device according to a seventh modification. FIG. 15 corresponds to FIG. 7 illustrating the above embodiment. The sealing member 50 is omitted from FIG. 15. The seventh modification differs from the first modification in that the spacers 33a and 33b composing the spacer 33 are directly coupled to each other without the joint layer 60 being interposed therebetween.

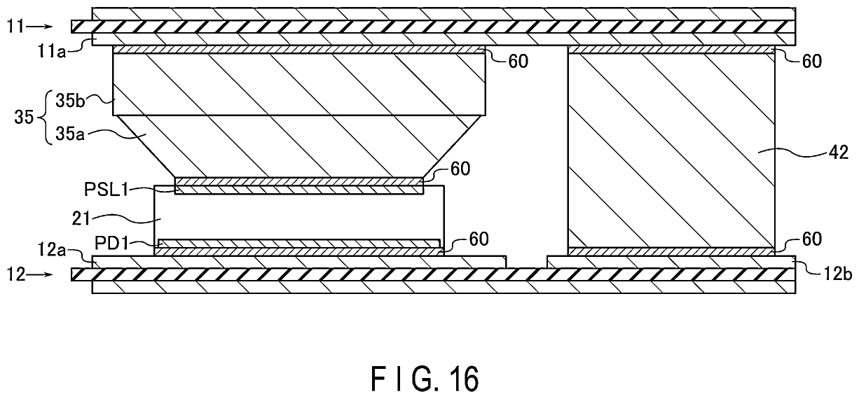

FIG. 16 is a cross-sectional view showing an example of an inner structure of a semiconductor device according to an eighth modification. FIG. 16 corresponds to FIG. 6 illustrating the above embodiment. The sealing member 50 is omitted from FIG. 16. The eighth modification differs from the second modification in that the spacers 35a and 35b composing the spacer 35 are directly coupled to each other without the joint layer 60 being interposed therebetween.

As described above, the spacer composed of the plurality of components described in the above embodiment and modifications may be configured in such a manner that a component and another component of the spacer may be directly coupled to each other.

In the case of the spacer composed of the plurality of components, the above embodiment and modifications described solder as an example of the joint layer joining a component to another component of the spacer. The joint layer that joins a component to another component of the spacer may be, for example, a silver sintered material.

As an example of a power module, the above embodiment and modifications described the power module including two transistors. The number of transistors included in the power module is not limited to two. The number of transistors included in the power module may be one, four, or six.

Throughout this description, “one end of a current path of a transistor” corresponds to a source or a drain of a MOS transistor. “The other end of the current path of the transistor” corresponds to a drain or a source of the MOS transistor.

Herein, the term “couple” refers to electrical coupling, and does not exclude intervention of another element. Expressions such as “electrically coupled” cover insulator-interposed coupling, which allows for the same operation as electrical coupling without an insulator.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first substrate;
a second substrate provided to face the first substrate;
a chip provided on the first substrate and between the first substrate and the second substrate; and
a spacer provided on the chip and coupling the chip and the second substrate,
wherein the spacer includes a first portion in contact with the chip and a second portion in contact with the second substrate, and the second portion is larger in area than the first portion.

2. The device according to claim 1, wherein the first portion of the spacer is fittable within a surface of the chip, the surface being in contact with the spacer.

3. The device according to claim 1, wherein the spacer is larger in thermal expansion coefficient than the chip and is smaller in thermal expansion coefficient than copper included in the first substrate and the second substrate.

4. The device according to claim 1, wherein
the chip includes a transistor, and
the spacer electrically couples one end of a current path of the transistor and the second substrate.

5. The device according to claim 1, wherein the spacer includes a portion in which a side wall is inclined from the first portion to the second portion.

6. The device according to claim 1, wherein the spacer includes a cross-sectional area on a plane in parallel to the first substrate, and the cross-sectional area continuously increases from the first portion to the second portion.

7. The device according to claim 1, wherein the spacer includes a first component including the first portion and a second component including the second portion, and the first component and the second component are joined via a joint layer.

8. The device according to claim 7, wherein the joint layer includes solder.

9. The device according to claim 1, wherein the spacer includes a first component including the first portion and a second component including the second portion, and the spacer has a shape in which the second component protrudes from all of four sides above the first component.

10. The device according to claim 1, wherein
the spacer includes a first component including the first portion, a second component including the second portion, and a third component provided between the first component and the second component,
the first component includes an upper surface and a lower surface which are fittable within an upper surface of the chip,
the third component includes an upper surface and a lower surface within which an upper surface of the first component is fittable, and
the second component includes an upper surface and a lower surface within which an upper surface of the third component is fittable.

11. The device according to claim 10, wherein the first component and the third component are joined via a joint layer, and the third component and the second component are joined via a joint layer.

12. The device according to claim 1, wherein the spacer includes a first component including the first portion and a second component including the second portion, and the first component and the second component are directly coupled not via a joint layer.
